(19) United States
(12) Patent Application Publication
(10) Pub. No.: US 2019/0363135 A1
(43) Pub. Date: Nov. 28, 2019

(54) RESISTIVE RANDOM ACCESS MEMORY CELL

(71) Applicant: Intel Corporation, Santa Clara, CA (US)

(72) Inventors: Prashant Majhi, San Jose, CA (US); Elijah V. Karpov, Portland, OR (US); Niloy Mukherjee, Beaverton, OR (US); James S. Clarke, Portland, OR (US); Ravi Pillarisetty, Portland, OR (US)

(73) Assignee: Intel Corporation, Santa Clara, CA (US)

(21) Appl. No.: 16/316,466

(22) PCT Filed: Sep. 29, 2016
(86) PCT No.: PCT/US2016/054299

§ 371 Date: Jan. 9, 2019

(51) Int. Cl. H01L 27/24; G11C 13/00

(52) U.S. Cl. CPC H01L 27/2436; H01L 45/1233; G11C 13/0097

(57) ABSTRACT

Substrates, assemblies, and techniques for enabling a resistive random access memory cell are disclosed herein. For example, in some embodiments, a device may include a source junction, a gate, a drain junction, a semiconductor located below the gate and between the source junction and the drain junction, and an insulator located below the semiconductor. The semiconductor can be used to tune a terminal voltage (Vt). In an example, the semiconductor is an extremely thin silicon on an insulator. In another example, the semiconductor is a fully depleted silicon-on-insulator or an extremely thin silicon on an insulator.

### CROSS-REFERENCE TO RELATED APPLICATION

This application is a national stage application under 35 U.S.C. § 371 of PCT International Application Serial No. PCT/US2016/054299, filed on Sep. 29, 2016 and entitled “Resistive Random Access Memory Cell,” which is hereby incorporated by reference herein in its entirety.

### TECHNICAL FIELD

The present disclosure relates generally to the field of memory cells, and more particularly, to resistive random access memory cells.

### BACKGROUND

Most, if not all, logic devices require some type of random access memory. Resistive random access memory (RRAM or ReRAM) is a type of non-volatile (NV) random access computer memory that works by changing the resistance across a dielectric solid-state material. RRAM can be similar to a memristor which is a hypothetical, non-linear, passive two-terminal electrical component relating electric charge and magnetic flux linkage. The memristor's electrical resistance is not constant but depends on the history of current that had previously flowed through the device. Its present resistance depends on how much electric charge flowed in what direction in the past. A RRAM cell is a device that remembers its history so when the electric power supply is turned off, the RRAM cell remembers its most recent resistance until it is turned on again. Using this property, the RRAM cell can be used as a memory cell or memory array for electronic devices. The cell transistors of the RRAM are usually engineered to a high Vt to be reliable at a high bias. However, the fixed Vt of the transistor results in a low drive strength.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a simplified block diagram illustrating an embodiment of a portion of an electronic device, in accordance with one embodiment of the present disclosure;

FIG. 2 is a simplified block diagram illustrating an embodiment of a portion of an electronic device, in accordance with one embodiment of the present disclosure;

FIG. 3 is a simplified graph illustrating example details of an electronic device, in accordance with one embodiment of the present disclosure;

FIG. 4 is a simplified graph illustrating example details of an electronic device, in accordance with one embodiment of the present disclosure;

FIG. 5 is an interposer implementing one or more of the embodiments disclosed herein; and

FIG. 6 is a computing device built in accordance with an embodiment disclosed herein.

The figures of the drawings are not necessarily drawn to scale, as their dimensions can be varied considerably without departing from the scope of the present disclosure.

### DETAILED DESCRIPTION

The following detailed description sets forth example embodiments of apparatuses, methods, and systems relating to a communication system for device pairing in a local network. Features such as structure(s), function(s), and/or characteristic(s), for example, are described with reference to one embodiment as a matter of convenience; various embodiments may be implemented with any suitable one or more of the described features.

In the following description, various aspects of the illustrative implementations will be described using terms commonly employed by those skilled in the art to convey the substance of their work to others skilled in the art. However, it will be apparent to those skilled in the art that the embodiments disclosed herein may be practiced with only some of the described aspects. For purposes of explanation, specific numbers, materials and configurations are set forth in order to provide a thorough understanding of the illustrative implementations. However, it will be apparent to one skilled in the art that the embodiments disclosed herein may be practiced without the specific details. In other instances, well-known features are omitted or simplified in order not to obscure the illustrative implementations.

Disclosed herein are substrates, assemblies, and techniques for enabling a device that includes one or more resistive random access memory cells. In some embodiments, the device may include a source, a gate, and a drain. The source, the gate, and the drain can be on top of a support substrate such as a semiconductor substrate. In an implementation, the substrate may be a non-silicon flexible substrate.

Various operations will be described as multiple discrete operations, in turn, in a manner that is most helpful in understanding the embodiments disclosed herein, however, the order of description should not be construed to imply that these operations are necessarily order dependent. In particular, these operations need not be performed in the order of presentation.

The terms “over,” “below,” “under,” “between,” and “on” as used herein refer to a relative position of one material layer or component with respect to other layers or components. For example, one layer disposed over, below, or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

Implementations of the embodiments disclosed herein may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. In other examples, the substrate may be a flexible substrate including 2D materials such as graphene and MoS2, organic materials such as pentacene, transparent oxides such as IGZO poly/amorphous (low temperature of dep) III-V semiconductors and Ge/Si, and other non-silicon flexible substrates. Although a few examples of materials from which the substrate may be formed are described here, any material that may serve as a foundation upon which a semiconductor device may be built falls within the spirit and scope of the embodiments disclosed herein.

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments. For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, a “package” and an “IC package” are synonymous. As used herein, the terms “chip” and “die” may be used interchangeably.

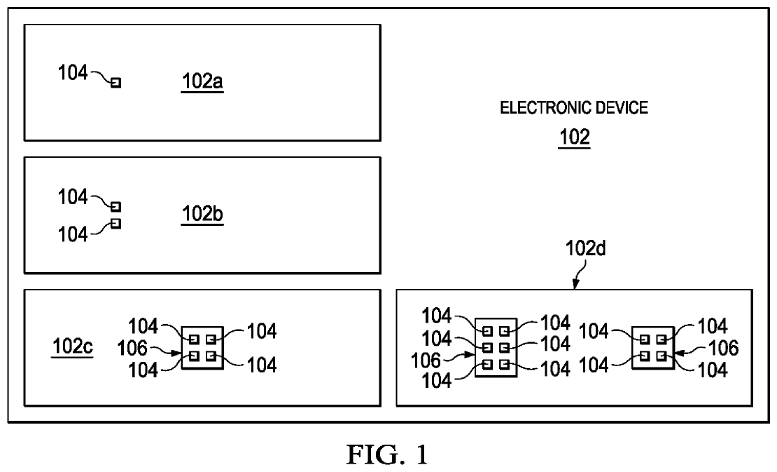

FIG. 1 is a simplified block diagram of an electronic device 100 that includes one or more resistive random access memory (RRAM) cells and arrays in accordance with an embodiment of the present disclosure. Electronic device 100 can include one or more electronic elements 102a-102d. Electronic device 100 can be any electronic device that includes memory (e.g., computer, smartphone, laptop, desktop, Internet-of-Things device, vehicle, handheld electronic device, personal digital assistant, wearable, etc.). Each electronic element 102a-102d can include a transistor 104 and/or one or more transistor arrays 106. Each transistor array 106 can be is a systematic arrangement of a plurality of transistors 104, (e.g., in rows and columns). Each transistor 104 can include a RRAM cell. Transistor 104 can be a transistor or an electronic switch that can be either in an “on” or “off” state and the term “transistor” includes a bipolar junction transistor (BJT), filed effect transistor (FET), finFET, junction gate FET (JFET), insulated-gate FET (IGFET), metal-oxide-semiconductor field-effect transistors (MOSFET), n-channel field-effect transistor (NFET) insulated-gate bipolar transistor, or other similar transistor that can be configured to perform the functions, features, and operations disclosed herein.

RRAM (or ReRAM) is a type of non-volatile (NV) random access computer memory that works by changing the resistance across a dielectric solid-state material. The cell transistors of the RRAM are typically engineered to a high Vt to be reliable at a high bias. However, the fixed Vt of the transistor results in a low drive strength in either SET or RESET operations of the RRAM due to the source follower condition in one of the polarities. The low drive strength can limit the switching currents used to operate the RRAM and result in low reliability of the RRAM cell and RRAM cell array.

Transistor 104 can be configured to resolve these issues (and others). For example, transistor 104 can be configured with an extremely thin silicon-on-insulator (ETSOI) or a fully depleted silicon-on-insulator (FDSOI) with thin buried oxide as the substrate to form the transistors that are connected to the RRAM. Back biasing can be used to dynamically tune the Vt of the transistor for the different polarities and hence circumvent the low drive strength in source follower condition (by reducing the Vt). Additionally, the ETSOI substrate allows for reduced junction leakage and low parasitic capacitance, both of which helps improve the performance/reliability of the 1T1R cells/arrays. The term “extremely thin silicon-on-insulator” or “ETSOI” refers to a silicon-on-insulator (SOI) that has a thickness in the range of about 10 nanometers (nm) to about 30 nm.

In an example, the threshold voltage of the transistor can be dynamically controlled for 1T1R memory cells. By using back bias in the ETSOI or FDSOI, the Vt can be dynamically controlled to reduce the Vt of the transistor in the polarity when the RRAM is in source follower condition for the transistor. This can effectively reduce the Vgs and allow for high drive currents, which improves the reliability of the RRAM cell/arrays. As a result, the high Vt related source degeneration issue for the 1T1R can be circumvented.

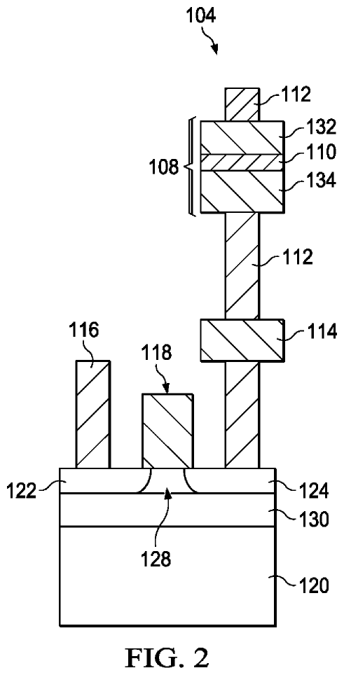

Turning to FIG. 2, FIG. 2 illustrates one embodiment of transistor 104. Transistor 104 can include, a RRAM stack 108, bit line 112, a connection 114, a source 116, a gate 118, a substrate 120, a source junction 122, a drain junction 124, a semiconductor 128, and an insulator 130. Transistor 104 can be configured to allow access to RRAM 110 and change the resistance of RRAM 110. For example, transistor 104 can be configured to program RRAM 110, deselect or not disturb RRAM 110, read RRAM 110, etc. Source junction 122 is the area or region interface where source 116 is coupled or connected to insulator 130 (e.g., the interface between source 116 and insulator 130). Drain junction 124 is the area or region interface where bit line 112 is coupled or connected to insulator 130 (e.g., the interface between bit line 112 and insulator 130). Source junction 122, drain junction 124, and semiconductor 128 are located on or over insulator 130 (or insulator 130 is located under source junction 122, drain junction 124, and semiconductor 128). For example, insulator 130 is located below source junction 122, drain junction 124, and semiconductor 128 when a plane include insulator 130 is between substrate 120 and a plane including source junction 122, drain junction 124, and semiconductor 128.

RRAM stack 108 can include RRAM 110, first metal 132, and second metal 134 and RRAM 110 can be located between first metal 132 and second metal 134. Bit line 112 can be a top electrode, bit line, and/or contact to RRAM 110. Connection 114 can be metal connections for transistor 104 and may be a metal connection from RRAM 110 to drain junction 124. More specifically, connection 114 can be part of a metal-2 or metal-3 extended connection. Source 116 may be a contact to source or source line. Gate 118 may be a gate or word line and can include a gate electrode and gate dielectric (not shown). In addition, source 116 and gate 118 may each be configured as a word line. Substrate 120 can be a silicon base substrate. Insulator 130 can include silicon oxide. Semiconductor 128 can be between source junction 122 and drain junction 124 and on insulator 130 to create an ETSOI or FDSOI transistor. Semiconductor 128 may be a thin silicon semiconductor, germanium (Ge), silicon germanium (SiGe), or other semiconducting material. In an example, semiconductor 128 can have a thickness is the range of about four (4) nm to about fifty (50) nm. In another example, semiconductor 128 may have a thickness in the range of about 10 nm to about 30 nm.

In a typical transistor, the stack is asymmetric. This means that the RRAM is connected to one side of the transistor (e.g., either the source side or the drain side). This asymmetry causes a difference in the effective biasing of the RRAM and causes a voltage drop during programing of the RRAM which leads to source follower issues.

More specifically, RRAM 110 can acquire its resistance by applying a bias which is created by running a current through bit line 112 and RRAM 110. Typically, a bipolar RRAM is used where a positive bias turns on the RRAM (i.e., a SET) and a negative bias turns off the RRAM (i.e., a RESET). To bias transistor 104, an electrical connection can be coupled to bit line 112, source 116, and gate 118.

In order to bias transistor 104 and SET RRAM 110, or turn RRAM 110 from an “off state” to an “on state,” a positive bias needs to be applied to RRAM 110. To achieve this, a positive voltage on bit line 112 can be biased positively with a high voltage, in the case of an NMOS transistor, gate 118 has to be biased positive and source 116 does not see any bias or would be biased to zero. In this example, gate 118 would turn on transistor 104 based on the difference between the voltages on gate 118 and source 116. In this biasing condition, RRAM 110 does not interfere and the voltage to turn on transistor 104 is the voltage on gate 118 minus the voltage on source 116. Once transistor 104 is turned on, its resistance is lowered significantly and most of the voltage applied to bit line 112 will be used by RRAM 110. By enabling transistor 104 to turn on with a low gate to source voltage (Vgs), the configuration of transistor 104 helps ensure that RRAM 110 sees most of the applied voltage to successfully program RRAM 110 or cause RRAM 110 to change its resistance.

To turn the RRAM off from a low resistance to a high resistance, different biases can be applied to bit line 112, source 116, and gate 118. For example, source 116 would now be a positive bias and bit line 112 would be biased to zero. Gate 118, would be biased to a positive voltage to turn on the transistor. Bit line 112 would be biased to zero.

In a conventional or typical transistor, this switches the current flow direction in the transistor and one problem or issue is that, for the transistor to turn on, the voltage from the gate to the source (Vgs) is typically greater than the threshold voltage of the transistor. The Vgs voltage is influenced by the voltage at the source, the voltage at the gate and the effective source voltage which is now on the bit line. An issue arises because the RRAM is in between the source and the gate and so the RRAM would significantly eat up the budget for the voltage to turn on the transistor which creates a source depletion or source following issue. This results in the need to apply a much higher voltage on the gate just to be able to turn on the transistor. The transistor needs to be turned on because once the transistor is turned on, it ensures that all the applied voltage would fall on the RRAM to ensure that the RRAM can successfully make the transition to the off state. In a regular transistor, since the RRAM is always connected to one side, it makes it asymmetric in terms or ability to provide or apply high voltages to the RRAM in a bipolar fashion. If an NMOS transistor is used, a high voltage and positive polarity can be provided but a high voltage cannot be applied on negative polarity. If a PMOS transistor is used, a high voltage on the negative polarity can be provided but a high voltage on the positive polarity cannot be provided because of the source follower configuration. As a result, a much higher voltage must be provided to effectively account for the voltage drop on the transistor as well as the RRAM. This causes the operating voltage of the transistor to be significant from an operating and power standpoint.

In a convention or typical transistor, to program RRAM 110 from an on state to an off state and negative polarity, the RRAM interferes and creates a source follower problem. In addition to the source follower issue of a conventional or typical transistor, the current process for creating the junctions of the transistor is prone to variability problems that often causes junction leakage and can result in problems in the off state power. In addition, due to the variability problems, the junction capacitance (any PN junction has a capacitance associated with it) could be significant enough to interfere with the ability to switch the RRAM under high speeds and the junction capacitance and result in resister/capacitance delays. In addition, the capacitance related to patristic discharge currents can interfere with proper operation of the RRAM.

However, transistor 104 can be configured with semiconductor 128 on insulator 130 and between source junction 122 and drain junction 124 to circumvent the source follower problem, at least to some extent, by biasing semiconductor 128 and changing the threshold voltage of transistor 104. Reducing the threshold voltage of transistor 104 allows transistor 104 to turn on or be activated at lower biases and as a result, gate 118 does not require a relatively high bias. Therefore, because transistor 104 includes semiconductor 128, transistor 104 can be configured as an engineered FDSOI or fully depleted SOI based transistor and the source follower issue can be at least partially addressed or resolved. In addition, because transistor 104 is an ETSOI or FDSOI transistor, it does not have or has reduced issues with junction leakage, junction capacitance, and other related issues.

As a result, there are not source follower problems as with current transistors and the bias is on bit line 112. Effectively, transistor 104 can be turned on with a low resistance and all the bias that is applied is on bit line 112 and RRAM 110. This allows for a successful transition from high resistance to low resistance using a relatively low voltage.

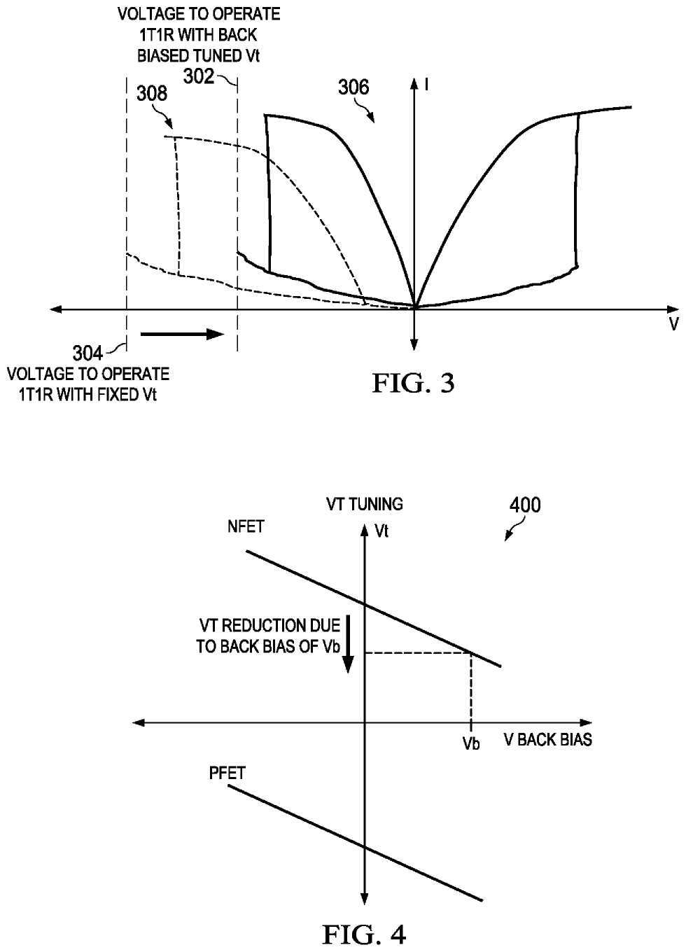

Turning to FIG. 3, FIG. 3 is a simplified graph illustrating example details of an electronic device, in accordance with one embodiment of the present disclosure. Graph 306 illustrates a current/voltage plot of 1T1R with a back biased tuned Vt using FDSOI. The FDSOI can be realized with semiconductor 128 on insulator 130 and between source junction 122 and drain junction 124. Partial graph 308 (illustrated with a dotted line) illustrates a current/voltage plot of a conventional or typical transistor with 1T1R and a fixed Vt. As illustrated in FIG. 3, a voltage 302 to operate 1T1R with a back biased tuned Vt is less than a voltage 304 to operate 1T1R with a fixed Vt as in a conventional transistor.

Turning to FIG. 4, FIG. 4 s a simplified graph illustrating example details of an electronic device, in accordance with one embodiment of the present disclosure. Graph 400 illustrates the relationship between the back biasing and the Vt for Vt tuning. Using semiconductor 128, the back biasing of transistor 104 can be tuned to a desired Vt. For ETSOI devices with thin buried oxide (e.g., semiconductor 128 being a thin Si and and insulator 130 being thin insulator), the threshold voltage (Vt) of the transistor, can be tuned by applying a bias to the substrate 120 and causing a back bias. For example, substrate 120 can be biased to tune the Vt of transistor 104 especially for a RESET condition, to circumvent the issue of source follower. The extent of Vt tuning that is possible for transistor 104 is related to the equation Vt=Vt(0)−G*Vb, where Vt is equal to the threshold voltage of transistor, Vt(0) is equal to the threshold voltage of transistor without any bias to substrate, Vb is equal to the bias on substrate 120, and G is equal to the coupling between substrate and channel (usually between 60-90 mV/V).

In the above examples, the semiconductor substrate for substrate 120 and semiconductor 128 (and any additional layers) may be formed using alternate materials, which may or may not be combined with silicon. This includes, but is not limited to, germanium, indium antimonide, lead telluride, indium arsenide, indium phosphide, gallium arsenide, indium gallium arsenide, gallium antimonide, or other combinations of group III-V or group IV materials. In other examples, the substrate of any layer may be a flexible substrate including 2D materials such as graphene and MoS2, organic materials such as pentacene, transparent oxides such as IGZO poly/amorphous (low temperature of dep) III-V semiconductors and Ge/Si, and other non-silicon flexible substrates.

In an example, a plurality of electrical components can include one or more transistors 104 and/or one or more transistor arrays 106. In addition, a plurality of transistors, such as MOSFET or simply MOS transistors) can include one or more transistors 104 and may be fabricated on the substrate. In various embodiments, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that various embodiments may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type work function metal or N-type work function metal, depending on whether the transistor is to be a PMOS or an NMOS transistor. In some implementations, the gate electrode layer may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a work function that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a work function that is between about 3.9 eV and about 4.2 eV.

In some implementations, when viewed as a cross-section of the transistor along the source-channel-drain direction, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

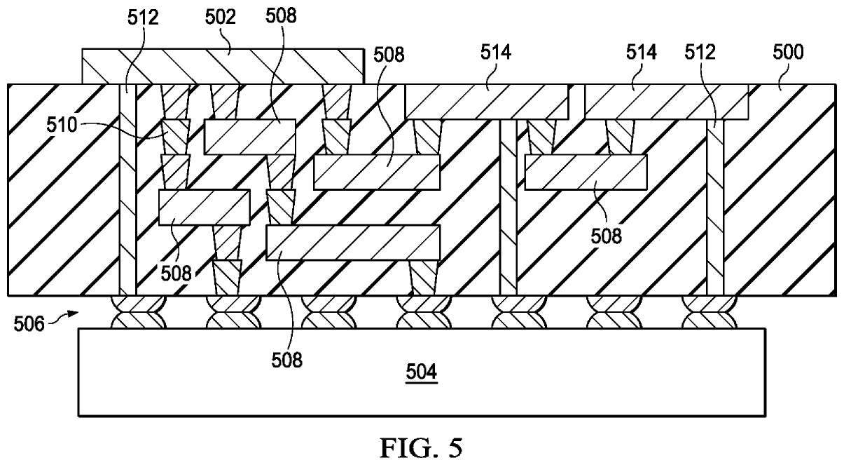

Turning to FIG. 5, FIG. 5 illustrates an interposer 500 that can include or interact with one or more embodiments disclosed herein. The interposer 500 is an intervening substrate used to bridge a first substrate 502 to a second substrate 504. The first substrate 502 may be, for instance, an integrated circuit die. The second substrate 504 may be, for instance, a memory module, a computer motherboard, or another integrated circuit die. Generally, the purpose of an interposer 500 is to spread a connection to a wider pitch or to reroute a connection to a different connection. For example, an interposer 500 may couple an integrated circuit die to a ball grid array (BGA) 506 that can subsequently be coupled to the second substrate 504. In some embodiments, the first and second substrates 502/504 are attached to opposing sides of the interposer 500. In other embodiments, the first and second substrates 502/504 are attached to the same side of the interposer 500. And in further embodiments, three or more substrates are interconnected by way of the interposer 500.

The interposer 500 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 508 and vias 510, including but not limited to through-silicon vias (TSVs) 512. The interposer 500 may further include embedded devices 514, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 500. In accordance with various embodiments, apparatuses or processes disclosed herein may be used in the fabrication of interposer 500.

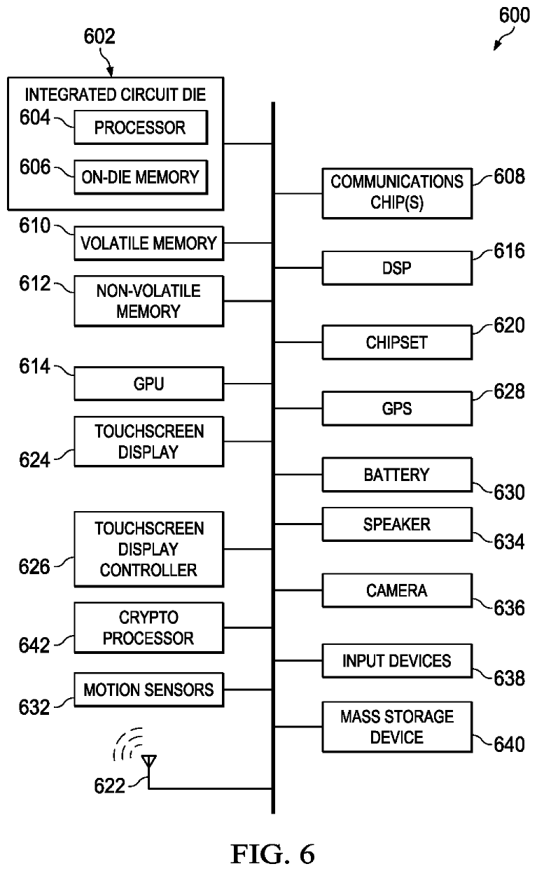

Turning to FIG. 6, FIG. 6 illustrates a computing device 600 in accordance with various embodiments. The computing device 600 may include a number of components. In one embodiment, these components are attached to one or more motherboards. In an alternate embodiment, some or all of these components are fabricated onto a single system-on-a-chip (SoC) die. The components in the computing device 600 include, but are not limited to, an integrated circuit die 602 and at least one communications logic unit 608. In some implementations the communications logic unit 608 is fabricated within the integrated circuit die 602 while in other implementations the communications logic unit 608 is fabricated in a separate integrated circuit chip that may be bonded to a substrate or motherboard that is shared with or electronically coupled to the integrated circuit die 602. The integrated circuit die 602 may include a CPU 604 as well as on-die memory 606, often used as cache memory, that can be provided by technologies such as embedded DRAM (eDRAM) or spin-transfer torque memory (STTM or STT-MRAM).

Computing device 600 may include other components that may or may not be physically and electrically coupled to the motherboard or fabricated within an SoC die. These other components include, but are not limited to, volatile memory 610 (e.g., DRAM), non-volatile memory 612 (e.g., ROM or flash memory), a graphics processing unit 614 (GPU), a digital signal processor 616, a crypto processor 642 (a specialized processor that executes cryptographic algorithms within hardware), a chipset 620, an antenna 622, a display or a touchscreen display 724, a touchscreen controller 626, a battery 630 or other power source, a power amplifier (not shown), a voltage regulator (not shown), a global positioning system (GPS) device 628, a compass 630, a motion coprocessor or sensors 632 (that may include an accelerometer, a gyroscope, and a compass), a speaker 634, a camera 636, user input devices 638 (such as a keyboard, mouse, stylus, and touchpad), and a mass storage device 640 (such as hard disk drive, compact disc (CD), digital versatile disk (DVD), and so forth).

The communications logic unit 608 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communications logic unit 608 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communications logic units 608. For instance, a first communications logic unit 608 may be dedicated to shorter range wireless communications such as Wi-Fi and Bluetooth and a second communications logic unit 608 may be dedicated to longer range wireless communications such as GPS, EDGE, GPRS, CDMA, WiMAX, LTE, Ev-DO, and others.

The processor 604 of the computing device 600 can communicate with one or more devices that are formed in accordance with various embodiments. The term “processor” may refer to any device or portion of a device that processes electronic data from registers and/or memory to transform that electronic data into other electronic data that may be stored in registers and/or memory.

The communications logic unit 608 may also include one or more devices, such as transistors or metal interconnects, that are in communication with various ones of the embodiments disclosed herein. In further embodiments, another component housed within the computing device 600 may contain one or more devices, such as transistors or metal interconnects, that are formed in accordance with implementations of the embodiments disclosed herein.

In various embodiments, the computing device 600 may be a laptop computer, a netbook computer, a notebook computer, an ultrabook computer, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 600 may be any other electronic device that processes data.

The above description of illustrated implementations, including what is described in the Abstract, is not intended to be exhaustive or to limit the scope of the disclosure to the precise forms disclosed. While specific implementations of, and examples for, the embodiments disclosed herein are described herein for illustrative purposes, various equivalent modifications are possible within the scope of the disclosure, as those skilled in the relevant art will recognize.

### Other Notes and Examples

Example 1 is an apparatus including a source junction, gate, a drain junction, a semiconductor located below the gate and between the source junction and the drain junction, and an insulator located below the semiconductor.

In Example 2, the subject matter of Example 1 can optionally include where the semiconductor can be used to tune a terminal voltage (Vt) of a transistor that includes the semiconductor.

In Example 3, the subject matter of any one of Examples 1 and 2 can optionally include where back biasing is used to turn the Vt.

In Example 4, the subject matter of any one of Examples 1-3 can optionally include where the apparatus is a transistor.

In Example 5, the subject matter of any one of Examples 1-4 can optionally include where the semiconductor is an extremely thin silicon on an insulator and may have a thickness of about ten (10) nanometers (nm) to about thirty (30) nm.

In Example 6, the subject matter of any one of Examples 1-5 can optionally include where the semiconductor is a fully depleted silicon-on-insulator.

In Example 7, the subject matter of any one of Examples 1-6 can optionally include where the drain junction is under a bit line or the bite line is on the drain junction.

In Example 8, the subject matter of any one of Examples 1-7 can optionally include where the bit line is coupled to resistive random access memory (RRAM).

In Example 9, a method can include tuning a terminal voltage (Vt) of a transistor, where the transistor includes a source junction, a gate, a drain junction, a semiconductor located below the gate and between the source junction and the drain junction, and an insulator located below the semiconductor, where the semiconductor is used to tune the Vt of the transistor.

In Example 10, the subject matter of Example 9 can optionally include where back biasing is used to turn the Vt.

In Example 11, the subject matter of any one of Examples 9 and 10 can optionally include where the semiconductor is an extremely thin silicon on an insulator and may have a thickness of about ten (10) nanometers (nm) to about thirty (30) nm.

In Example 12, the subject matter of any one of Examples 9-11 can optionally include where the semiconductor is a fully depleted silicon-on-insulator.

In Example 13, the subject matter of any one of Examples 9-12 can optionally include where the drain junction is under a bit line or the bite line is on the drain junction.

In Example 14, the subject matter of any one of Examples 9-13 can optionally include where the bit line is coupled to resistive random access memory (RRAM).

Example 15 is a computing device including a processor mounted on a substrate, a communications logic unit within the processor, a memory within the processor, a graphics processing unit within the computing device, an antenna within the computing device, a display on the computing device, a battery within the computing device, a power amplifier within the processor, and a voltage regulator within the processor. The memory can include a source junction, a gate, a drain junction, a semiconductor located below the gate and between the source junction and the drain junction, and an insulator located below the semiconductor.

In Example 16 the subject matter of Example 15 can optionally include where the semiconductor can be used to tune a terminal voltage (Vt) of a transistor that includes the semiconductor.

In Example 17 the subject matter of any one of Examples 15 and 16 can optionally include where back biasing is used to turn the Vt.

In Example 18, the subject matter of Example 15-17 can optionally include where the semiconductor is an extremely thin silicon on an insulator and may have a thickness of about ten (10) nanometers (nm) to about thirty (30) nm.

In Example 19, the subject matter of any one of the Examples 15-18 can optionally include where the semiconductor is a fully depleted silicon-on-insulator.

In Example 20, the subject matter of any one of the Examples 15-19 can optionally include where the drain junction is under a bit line and the bit line is coupled to resistive random access memory (RRAM).

Example 21 is an integrated circuit (IC) assembly including a substrate, an insulator located above the substrate, a semiconductor located above the insulator, a source junction located above the insulator, a gate located above the semiconductor, and a drain junction located above the insulator, where the semiconductor is located between the source junction and the drain junction.

In Example 22, the subject matter of Example 21 can optionally include where the semiconductor can be used to tune a terminal voltage (Vt) of a transistor that includes the semiconductor.

In Example 23, the subject matter of any one of the Examples 21 and 22-23 can optionally include where back biasing is used to turn the Vt.

In Example 24, the subject matter of any one of the Examples 21-23 can optionally include where the semiconductor is an extremely thin silicon on an insulator and may have a thickness of about ten (10) nanometers (nm) to about thirty (30) nm.

In Example 25, the subject matter of any one of the Examples 22-24 can optionally include where the semiconductor is a fully depleted silicon-on-insulator.

1-25. (canceled)

26. A memory device, comprising:
a bit line; and
a transistor electrically coupled to the bit line, wherein the transistor includes:
a source junction,
a gate,
a drain junction,
a semiconductor below the gate and between the source junction and the drain junction, and
an insulator below the semiconductor.

27. The memory device of claim 26, wherein biasing the semiconductor tunes a terminal voltage (Vt) of the transistor.

28. The memory device of claim 26, wherein the semiconductor and insulator are a fully depleted silicon-on-insulator (ETSOI) structure.

29. The memory device of claim 26, wherein the semiconductor and insulator are an extremely thin silicon-on-insulator structure.

30. The memory device of claim 26, wherein a thickness of the semiconductor is between 10 nanometers and 30 nanometers.

31. The memory device of claim 26, wherein the drain junction is under a bit line of a memory device.

32. The memory device of claim 31, wherein the bit line is coupled to a resistive random access memory (RRAM) element.

33. The memory device of claim 32, wherein the bit line is coupled to an array of RRAM elements.

34. A method of adjusting drive strength in a memory device, comprising:
biasing a semiconductor layer of a transistor, wherein the transistor includes a source junction, a gate, a drain junction, the semiconductor layer, and an insulator below the semiconductor layer, wherein the semiconductor layer is below the gate and between the source junction and the drain junction; and
performing a SET or RESET operation on a resistive random access memory (RRAM) element electrically coupled to the transistor.

35. The method of claim 34, wherein the semiconductor layer and the insulator together are an extremely thin silicon-on-insulator (ETSOI) structure.

36. The method of claim 34, wherein the semiconductor layer and the insulator together are a fully depleted silicon-on-insulator (FDSOI) structure.

37. The method of claim 34, wherein the drain junction is under a bit line of the memory device, and the bit line is coupled to the RRAM element.

38. The method of claim 34, wherein a thickness of the semiconductor layer is between 10 nanometers and 30 nanometers.

39. A computing device, comprising:
a circuit board; and
a memory device coupled to the circuit board, wherein the memory device includes:
a bit line, and
a transistor electrically coupled to the bit line, wherein the transistor includes a gate, a semiconductor below the gate, and an insulator below the semiconductor, wherein the semiconductor has a thickness between 10 nanometers and 30 nanometers.

40. The computing device of claim 39, wherein the transistor is part of a 1 transistor-1 resistor (1T1R) memory cell.

41. The computing device of claim 39, wherein the semiconductor is fully depleted silicon.

42. The computing device of claim 39, wherein the memory device further includes a resistive random access memory (RRAM) element coupled to the bit line.

43. The computing device of claim 42, wherein back biasing the semiconductor adjusts a drive strength of the transistor during SET or RESET operations on the RRAM element.

44. The computing device of claim 39, further comprising:
a processing device coupled to the circuit board.

45. The computing device of claim 39, wherein the computing device is a handheld computing device or a server computing device.
